(19) United States
(12) Patent Application Publication
(10) Pub. No.: US 2024/0079327 A1
(43) Pub. Date: Mar. 7, 2024

(54) BACKSIDE POWER ELEMENT CONNECTION TO SOURCE/DRAIN REGION

(71) Applicant: International Business Machines Corporation, Armonk, NY (US)

(72) Inventors: Ruilong Xie, Niskayuna, NY (US); Theodorus E. Standaert, Clifton Park, NY (US); Nicolas Jean Loubet, Guilderland, NY (US); Kisik Choi, Watervliet, NY (US)

(21) Appl. No.: 17/939,422

(22) Filed: Sep. 7, 2022

(51) Int. Cl. H01L 23/528; H01L 23/48; H01L 29/06; H01L 29/40; H01L 29/417; H01L 29/423; H01L 29/775; H01L 29/786

(52) U.S. Cl. CPC H01L 23/5286; H01L 23/481; H01L 29/0673; H01L 29/401; H01L 29/41733; H01L 29/42392; H01L 29/775; H01L 29/78696

(57) ABSTRACT

A semiconductor device includes a transistor disposed on a semiconductor substrate, wherein the transistor includes a source/drain region disposed on a first side of the semiconductor substrate. A via extends through the semiconductor substrate, and connects a power element disposed on a second side of the semiconductor substrate to the source/drain region. A dielectric spacer is disposed between the via and the semiconductor substrate.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming a connection to a backside power element for a source/drain region of a semiconductor device.

In one embodiment, a semiconductor device includes a transistor disposed on a semiconductor substrate, wherein the transistor includes a source/drain region disposed on a first side of the semiconductor substrate. A via extends through the semiconductor substrate, and connects a power element disposed on a second side of the semiconductor substrate to the source/drain region. A dielectric spacer is disposed between the via and the semiconductor substrate.

In another embodiment, an integrated circuit includes a transistor disposed on a semiconductor layer, wherein the transistor includes a source/drain region disposed on a first side of the semiconductor layer. An isolation region is disposed in the semiconductor layer, and a via extends through the semiconductor layer. The isolation region is disposed between the via and the semiconductor layer. The via connects a power element disposed on a second side of the semiconductor layer to the source/drain region.

In another embodiment, a semiconductor device includes a source/drain region disposed on a first side of a semiconductor layer, a power element disposed on a second side of the semiconductor layer, and a via extending through the semiconductor layer and between the power element and the source/drain region.

These and other features and advantages of embodiments described herein will become more apparent from the accompanying drawings and the following detailed description.

### BRIEF DESCRIPTION OF THE DRAWINGS

FIG. 1 is a schematic top view of a transistor structure, according to an embodiment of the invention.

FIG. 2A is a schematic cross-sectional view taken along a first y-axis and illustrating middle-of-line (MOL) contact formation, back-end-of-line (BEOL) interconnect formation and carrier wafer bonding in connection with a transistor structure, according to an embodiment of the invention.

FIG. 2B is a schematic cross-sectional view taken along a second y-axis and illustrating MOL contact formation, BEOL interconnect formation and carrier wafer bonding in connection with a transistor structure, according to an embodiment of the invention.

FIG. 2C is a schematic cross-sectional view taken along an x-axis and illustrating MOL contact formation, BEOL interconnect formation and carrier wafer bonding in connection with a transistor structure, according to an embodiment of the invention.

FIG. 3A is a schematic cross-sectional view taken along the first y-axis and illustrating substrate removal from the FIG. 2A structure, according to an embodiment of the invention.

FIG. 3B is a schematic cross-sectional view taken along the second y-axis and illustrating substrate removal from the FIG. 2B structure, according to an embodiment of the invention.

FIG. 3C is a schematic cross-sectional view taken along the x-axis and illustrating substrate removal from the FIG. 2C structure, according to an embodiment of the invention.

FIG. 4A is a schematic cross-sectional view taken along the first y-axis and illustrating etch stop layer and selective semiconductor layer removal from the FIG. 3A structure, according to an embodiment of the invention.

FIG. 4B is a schematic cross-sectional view taken along the second y-axis and illustrating etch stop layer and selective semiconductor layer removal from the FIG. 3B structure, according to an embodiment of the invention.

FIG. 4C is a schematic cross-sectional view taken along the x-axis and illustrating etch stop layer and selective semiconductor layer removal from the FIG. 3C structure, according to an embodiment of the invention.

FIG. 5 is a schematic cross-sectional view taken along the first y-axis and illustrating selective trimming of an exposed isolation layer from the FIG. 4A structure, according to an embodiment of the invention.

FIG. 6A is a schematic cross-sectional view taken along the first y-axis and illustrating selective exposed semiconductor layer trimming from the FIG. 5 structure, according to an embodiment of the invention.

FIG. 6B is a schematic cross-sectional view taken along the second y-axis and illustrating a structure following selective exposed semiconductor layer trimming, according to an embodiment of the invention.

FIG. 6C is a schematic cross-sectional view taken along the x-axis and illustrating a structure following selective exposed semiconductor layer trimming, according to an embodiment of the invention.

FIG. 7A is a schematic cross-sectional view taken along the first y-axis and illustrating sidewall spacer formation on the FIG. 6A structure, according to an embodiment of the invention.

FIG. 7B is a schematic cross-sectional view taken along the x-axis and illustrating sidewall spacer formation on the FIG. 6C structure, according to an embodiment of the invention.

FIG. 8A is a schematic cross-sectional view taken along the first y-axis and illustrating backside contact metallization and planarization of the FIG. 7A structure, according to an embodiment of the invention.

FIG. 8B is a schematic cross-sectional view taken along the second y-axis and illustrating a structure following backside contact metallization and planarization, according to an embodiment of the invention.

FIG. 8C is a schematic cross-sectional view taken along the x-axis and illustrating backside contact metallization and planarization of the FIG. 7B structure, according to an embodiment of the invention.

FIG. 9A is a schematic cross-sectional view taken along the first y-axis and illustrating selective semiconductor layer recessing of the FIG. 8A structure, according to an embodiment of the invention.

FIG. 9B is a schematic cross-sectional view taken along the second y-axis and illustrating selective semiconductor layer recessing of the FIG. 8B structure, according to an embodiment of the invention.

FIG. 9C is a schematic cross-sectional view taken along the x-axis and illustrating selective semiconductor layer recessing of the FIG. 8C structure, according to an embodiment of the invention.

FIG. 10A is a schematic cross-sectional view taken along the first y-axis and illustrating backside inter-layer dielectric (ILD) deposition on the FIG. 9A structure, according to an embodiment of the invention.

FIG. 10B is a schematic cross-sectional view taken along the second y-axis and illustrating backside ILD deposition on the FIG. 9B structure, according to an embodiment of the invention.

FIG. 10C is a schematic cross-sectional view taken along the x-axis and illustrating backside ILD deposition on the FIG. 9C structure, according to an embodiment of the invention.

FIG. 11A is a schematic cross-sectional view taken along the first y-axis and illustrating power element and power delivery network layer formation on the FIG. 10A structure, according to an embodiment of the invention.

FIG. 11B is a schematic cross-sectional view taken along the second y-axis and illustrating power element and power delivery network layer formation on the FIG. 10B structure, according to an embodiment of the invention.

FIG. 11C is a schematic cross-sectional view taken along the x-axis and illustrating power element and power delivery network layer formation on the FIG. 10C structure, according to an embodiment of the invention.

FIG. 12 depicts a block diagram of an integrated circuit comprising one or more semiconductor devices with a backside power element connection for a source/drain region, according to an embodiment of the invention.

### DETAILED DESCRIPTION

Illustrative embodiments of the invention may be described herein in the context of illustrative methods for forming a backside power element connection to a source/drain region, where a dielectric sidewall spacer separates a backside via from a semiconductor layer, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers may be used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (NFET and PFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

As discussed above, various techniques may be used to reduce the size of FETs, including through the use of fin-shaped channels in FinFET devices, and through the use of stacked nanosheet channels formed over a semiconductor substrate.

As used herein, “frontside or “first side” refers to a side on top of the first and second semiconductor substrates 101 and 103 in the orientation shown in the cross-sectional figures. As used herein, “backside” or “second side” refers to a side below the first and/or second semiconductor substrates 101 and 103 in the orientation shown in the cross-sectional figures (e.g., opposite the “frontside”).

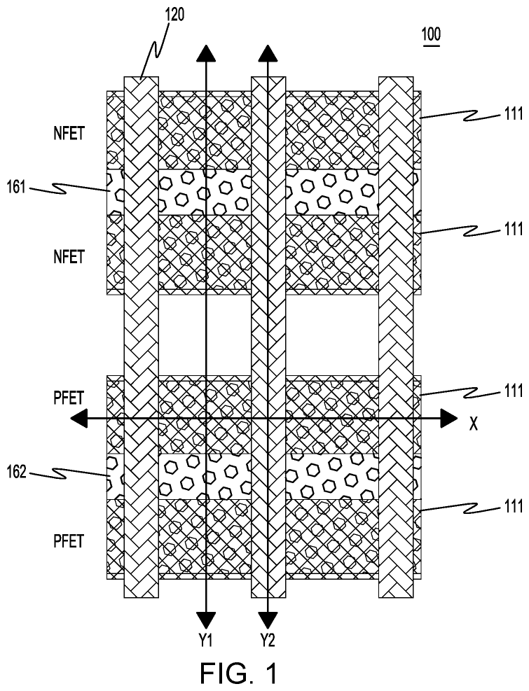

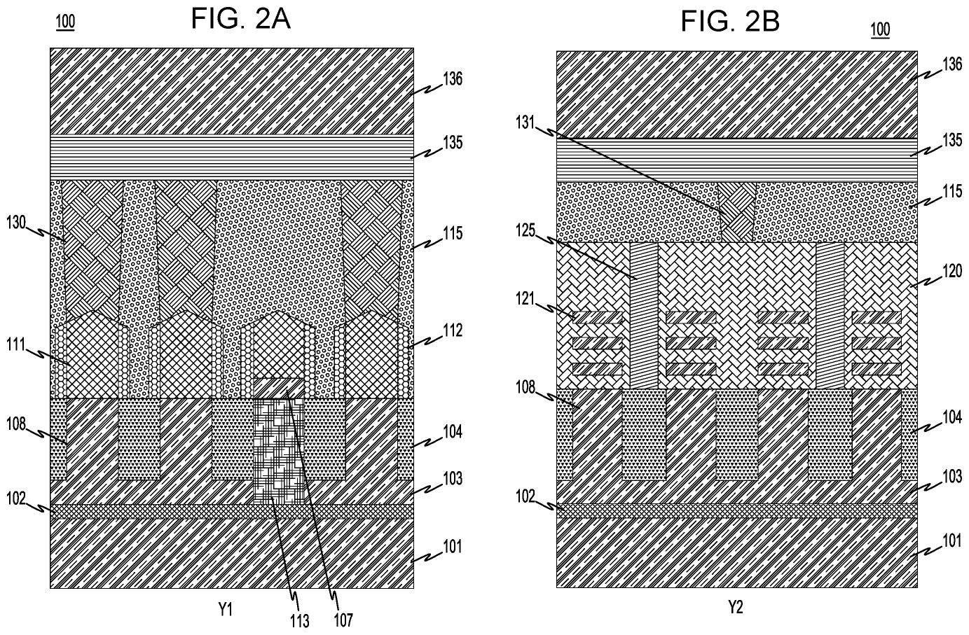

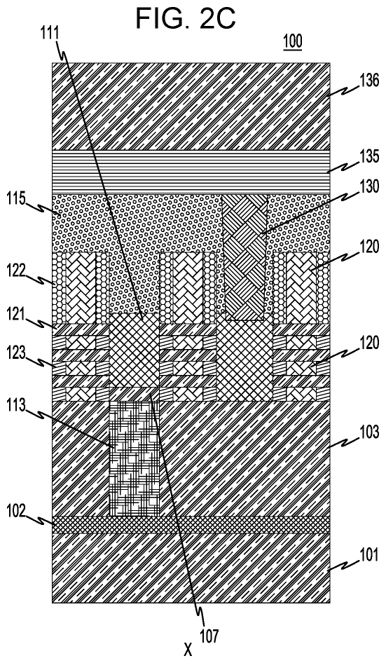

FIG. 1 is a schematic top view of a semiconductor device 100 having a transistor structure. FIGS. 2A, 2B and 2C are schematic cross-sectional views taken along a first y-axis (Y1 in FIG. 1), a second y-axis (Y2 in FIG. 1) and an x-axis (X in FIG. 1), and illustrating middle-of-line (MOL) contact formation, back-end-of-line (BEOL) interconnect formation and carrier wafer bonding in connection with the transistor structure, according to an embodiment of the invention.

Referring to FIGS. 2A, 2B and 2C, first and second semiconductor substrates 101 and 103 comprise semiconductor material including, but not limited to, silicon (Si), III-V, II-V compound semiconductor materials or other like semiconductor materials. In addition, multiple layers of the semiconductor materials can be used as the semiconductor material of the first and second semiconductor substrates 101 and 103. An etch stop layer 102 is formed on the first semiconductor substrate 101, and may comprise, for example, silicon oxide (SiOₓ) (where x is for example, 2, 1.99 or 2.01), or silicon germanium (SiGe). The second semiconductor substrate 103 comprising, for example, the same semiconductor material as the first semiconductor substrate 101, or other like semiconductor material, is formed on the etch stop layer 102.

Portions of the second semiconductor substrate 103 are recessed to a lower height to form a plurality of pedestal portions 108 at a greater height above the first semiconductor substrate 101 than the recessed portions. In illustrative embodiments, a width of the pedestal portions 108 (horizontal direction in FIGS. 2A and 2B) corresponds to the size of source/drain regions 111 in the same direction. A dielectric layer 104 fills in the recessed portions of the second semiconductor substrate 103 between the pedestal portions 108 to form a plurality of isolation regions (e.g., shallow trench isolation (STI) regions). The dielectric layer 104 may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

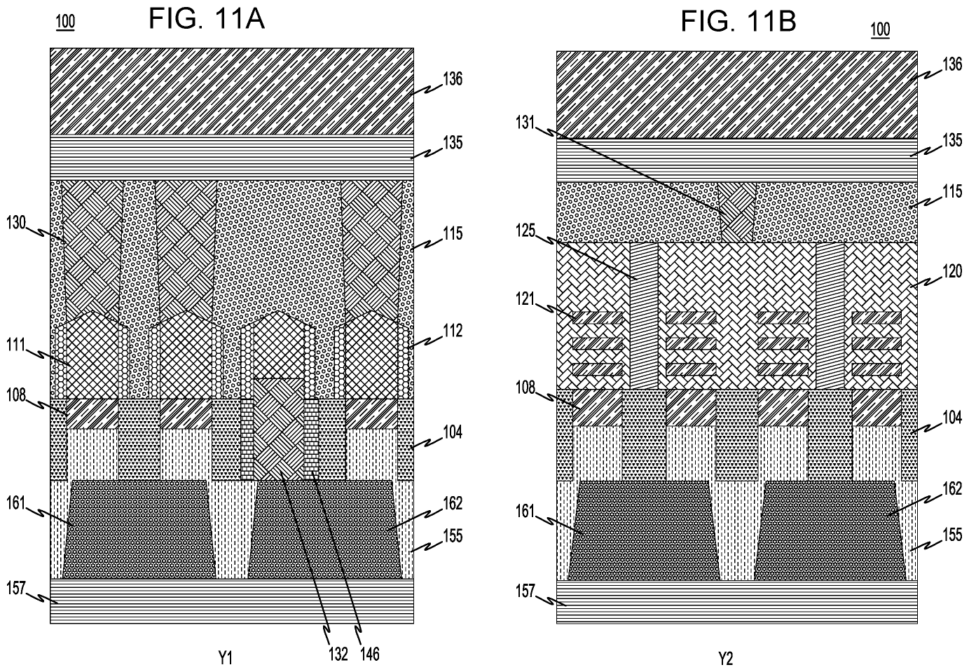

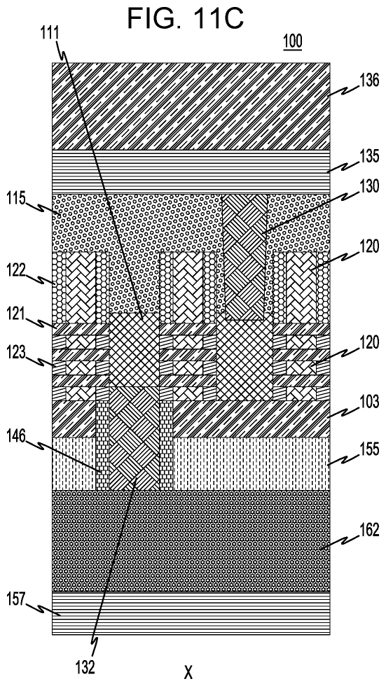

FIG. 1 depicts a simplified top view of the semiconductor device 100, showing the gate layers 120, source/drain regions 111 and backside power rails 161 and 162. The backside power rails 161 and 162 (also referred to herein as “backside power elements” or “power elements”) are explained in more detail herein in connection with FIGS. 11A, 11B and 11C. FIG. 1 further illustrates a possible configuration of n-type FETs (NFETs) and p-type (PFETs). The schematic cross-sectional views shown in FIGS. 2A, 3A, 4A, 5, 6A, 7A, 8A, 9A, 10A and 11A correspond to the Y1 axis in FIG. 1. The schematic cross-sectional views shown in FIGS. 2B, 3B, 4B, 6B, 8B, 9B, 10B and 11B correspond to the Y2 axis in FIG. 1. The schematic cross-sectional views shown in FIGS. 2C, 3C, 4C, 6C, 7B, 8C, 9C, 10C and 11C correspond to the X axis in FIG. 1.

The stacked transistor structure includes nanosheet transistors having an alternating structure of gate layers 120 and nanosheet channel layers 121, with source/drain regions 111 extending from the nanosheet channel layers 121. As can be seen, three nanosheet channel layers 121 are alternately stacked with four gate layers 120 in a configuration starting with a lowermost nanosheet channel layer 121 stacked on a lowermost gate layer 120. The number of gate layers 120 and channel layers 121 in a given transistor stack can vary and is not necessarily limited to the illustrated number of gate and nanosheet channel layers 120 and 121. The nanosheet channel layers 121 may be formed of Si or another suitable material (e.g., a material similar to that used for the first and second semiconductor substrates 101 and 103). Each of the nanosheet channel layers 121 may have a thickness (in vertical direction in FIGS. 2B and 2C) in the range of about 4 nm-about 10 nm.

Gate spacers 122 and inner spacers 123 are positioned on opposite lateral sides of the gate layers 120 of the transistors. Source/drain region spacers 112 are positioned on opposite lateral sides of the source/drain regions 111 of the transistors. The gate spacers 122 and inner spacers 123 are formed on sides of the gate layers 120, and source/drain region spacers 112 are formed on sides of the source/drain regions 111. The gate spacers 122, inner spacers 123 and source/drain region spacers 112 can be formed using deposition techniques such as, for example, CVD, PECVD, RFCVD, PVD, ALD, MBD, PLD, LSMCD, etc., followed by isotropic etching or directional etching. Directional etching may include but is not limited to, reactive ion etching (ME). The gate spacers 122, inner spacers 123 and source/drain region spacers 112 are formed from material comprising for example, one or more dielectrics, including, but not necessarily limited to, SiN, silicon carbide (SiC), SiON, SiOC, SiCN, BN, SiBN, SiBCN, SiOCN, SiOₓ, and combinations thereof. In a non-limiting illustrative embodiment, at least some of the gate spacers 122, inner spacers 123 and source/drain region spacers 112 may comprise the same material.

The source/drain regions 111 comprise epitaxial layers grown from sides of the nanosheet channel layers 121. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

According to a non-limiting embodiment of the present invention, the conditions of the epitaxial growth process for the source/drain regions 111 are, for example, RTCVD epitaxial growth using SiH₄, SiH₂Cl₂, GeH₄, CH₃SiH₃, B₂H₆, PF₃, and/or H₂ gases with temperature and pressure range of about 450° C. to about 800° C., and about 5 Torr-about 300 Torr. Embodiments of the present invention may be described in connection with source/drain regions for NFETs comprising, for example, Si source/drain regions, and source/drain regions for PFETs comprising, for example, silicon germanium source/drain regions.

The source/drain regions 111, as noted above, may be formed using epitaxial growth processes, and thus may also be referred to as epitaxial layers 111. The source/drain regions 111 may be suitably doped, such as by using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl).

In non-limiting illustrative embodiments, the source/drain regions 111 can comprise in-situ phosphorous doped (ISPD) silicon or Si:C for n-type devices, or in-situ boron doped (ISBD) silicon germanium for p-type devices, at concentrations of about 1×10¹⁹/cm³ to about 3×10²¹/cm³. By “in-situ,” it is meant that the dopant that dictates the conductivity type of the doped layer is introduced during the process step, e.g., epitaxial deposition, which forms the doped layer. The source/drain regions 111 may have a width (in horizontal direction in FIG. 2C) in the range of about 10 nm to about 30 nm.

The gate layers 120 may comprise a gate dielectric layer and a gate conductor layer. The gate dielectric layer may be formed of a high-k dielectric material. Examples of high-k dielectric materials include, but are not limited to, metal oxides such as HfO₂ (hafnium oxide), hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate dielectric layer may have a uniform thickness in the range of about 1 nm to about 3 nm.

The gate conductor layer may include a metal gate and/or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. A metal gate layer including, but not necessarily limited to, metals, such as, for example, tungsten, cobalt, zirconium, ruthenium, copper, metal carbides, metal nitrides, transition metal aluminides, tantalum carbide, titanium carbide, tantalum magnesium carbide, or combinations thereof may be deposited on the WFM layer. It should be appreciated that various other materials may be used for the gate conductor layer as desired.

An inter-layer dielectric (ILD) layer 115 is formed between, on top of and around the nanosheet stacks, gate layers 120 and source/drain regions 111. The ILD layer 115 may be formed of any suitable isolating material, such as SiOₓ, silicon oxycarbide (SiOC), SiOCN or some other dielectric.

As shown in FIGS. 2A and 2C, a semiconductor layer 107 and a sacrificial semiconductor layer 113 are formed under at least one of the source/drain regions 111. According to illustrative embodiments, the semiconductor layer 107 comprises a same or similar material to that of the first and second semiconductor substrates 101 and 103 (e.g., silicon) and the sacrificial semiconductor layer 113 comprises, for example, SiGe. The sacrificial semiconductor layer 113 and semiconductor layer 107 can be formed by defining a deep trench by lithography patterning and etching, followed by bottom-up epitaxial growth of the sacrificial semiconductor layer 113 and the semiconductor layer 107 sequentially. After formation of the sacrificial semiconductor layer 113 and semiconductor layer 107, the source/drain region 111 can grow epitaxially above the semiconductor layer 107.

FIG. 2B illustrates gate cut regions 125, which separate and isolate gate layers 120 from each other. The gate spacers 122, inner spacers 123, gate cut regions 125 and source/drain region spacers 112 are formed from material comprising for example, one or more dielectrics, including, but not necessarily limited to, SiN, silicon carbide (SiC), SiON, SiOC, SiCN, BN, SiBN, SiBCN, SiOCN, SiOₓ, and combinations thereof.

Frontside source/drain contact vias 130 and a frontside gate contact via 131 are formed in the ILD layer 115. In forming the frontside source/drain and gate contact vias 130 and 131, via openings are formed through portions of the ILD layer 115. The via openings expose portions the source/drain regions 111 and gate layers 120 of transistors on which the frontside source/drain and gate contact vias 130 and 131 are to be formed. According to an embodiment, masks are formed on parts of the ILD layer 115, and exposed portions of the ILD layer 115 corresponding to where the via openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers are deposited in the via openings to form the frontside source/drain and gate contact vias 130 and 131. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, chemical mechanical planarization (CMP) to remove excess portions of the metal layers from on top of the ILD layer 115. The number and locations of the frontside source/drain and gate contact vias 130 and 131 are not necessarily limited to what is shown in FIGS. 2A-2C, and may vary depending on design constraints. For example, there may be more or less source/drain and gate contact vias 130 and 131 than what is shown.

The frontside source/drain contact vias 130 contact respective ones of the source/drain regions 111, and the frontside gate contact via 131 contacts a gate layer 120. The frontside source/drain and gate contact vias 130 and 131 extends through the ILD layer 115 to land on and contact the corresponding source/drain regions 111 and gate layers 120.

Frontside BEOL interconnects 135 are formed on the ILD layer 115 including the frontside source/drain and gate contact vias 130 and 131. A carrier wafer 136 is bonded to the frontside BEOL interconnects 135. The frontside BEOL interconnects 135 include various BEOL interconnect structures which may electrically connect to the frontside source/drain and gate contact vias 130 and 131. The carrier wafer 136 may be formed of materials similar to that of the first and second semiconductor substrates 101 and 103, and may be formed over the frontside BEOL interconnects 135 using a wafer bonding process, such as dielectric-to-dielectric bonding.

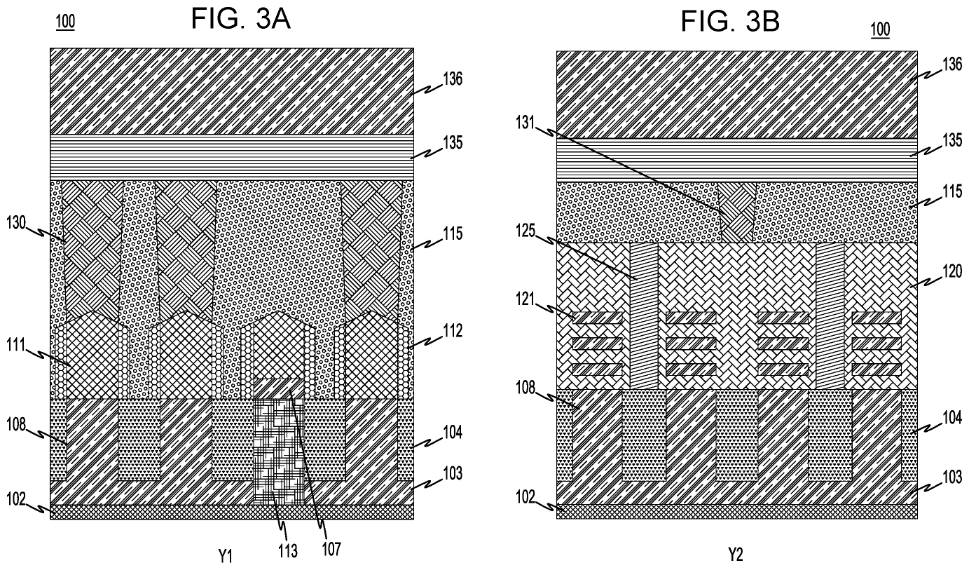

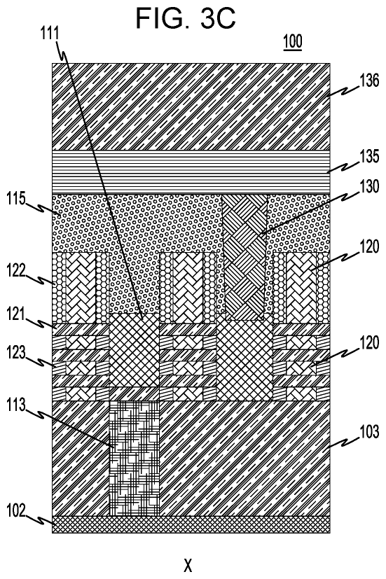

FIGS. 3A, 3B and 3C are schematic cross-sectional views taken along the first y-axis, the second y-axis and the x-axis, and illustrating removal of the first semiconductor substrate 101 from the FIG. 2A-2C structures. Using the carrier wafer 136, the semiconductor device 100 shown in FIGS. 2A-2C may be “flipped” (e.g., rotated 180 degrees) so that the structure is inverted. In addition, the first semiconductor substrate 101 is removed from the backside of the semiconductor device 100. The removal process, which comprises etching of the first semiconductor substrate 101, stops at the etch stop layer 102 as illustrated in FIGS. 3A-3C. For example, the first semiconductor substrate 101 is selectively etched with an etchant that selectively etches silicon with respect to a material of the etch stop layer 102 (e.g., SiO₂ or SiGe).

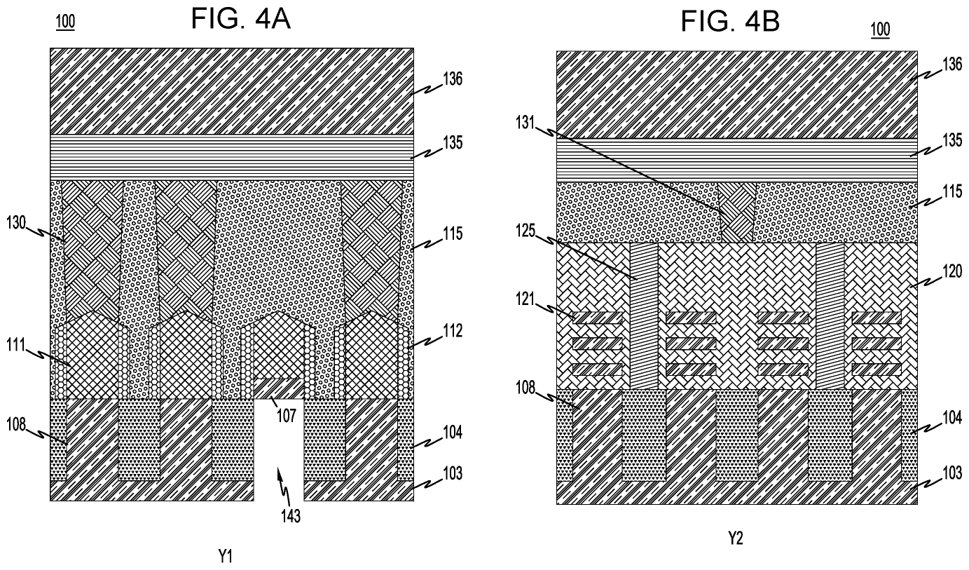

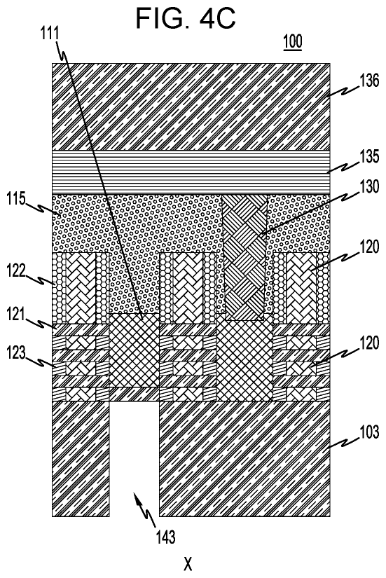

FIGS. 4A, 4B and 4C are schematic cross-sectional views taken along the first y-axis, the second y-axis and the x-axis, and illustrating removal of the etch stop layer 102 and selective removal of the sacrificial semiconductor layer 113 from the semiconductor device 100 shown in FIGS. 3A-3C. As shown in FIGS. 4A-4C, the etch stop layer 102 is removed, followed by removal of the sacrificial semiconductor layer 113 to create a backside contact trench 143, wherein portions of the dielectric layer 104 (e.g., STI region), and the semiconductor layer 107 are exposed. Etching processes for removal of the etch stop layer 102 include, for example, IBE by Ar/CHF3 based chemistry.

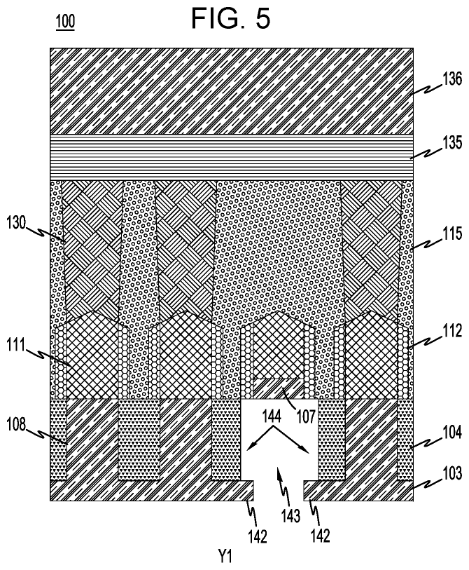

FIG. 5 is a schematic cross-sectional view taken along the first y-axis and illustrating selective trimming of exposed portions of the dielectric layer 104 (e.g., isolation region) from the FIG. 4A structure. As shown in FIG. 5, portions of the dielectric layer 104 are removed to increase the area of the backside contact trench 143 by an amount corresponding to the vacant areas 144 left by the removal of the portions of the dielectric layer 104. Etching processes for removal of the portions of the dielectric layer 104 include, for example, dilute hydrofluoric acid (DHF) wet clean or SiCoNi dry etch.

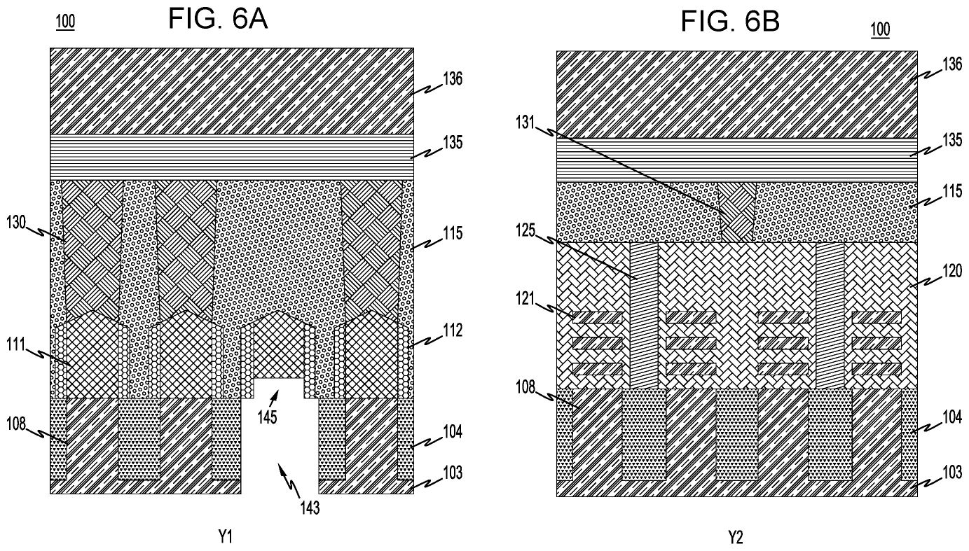

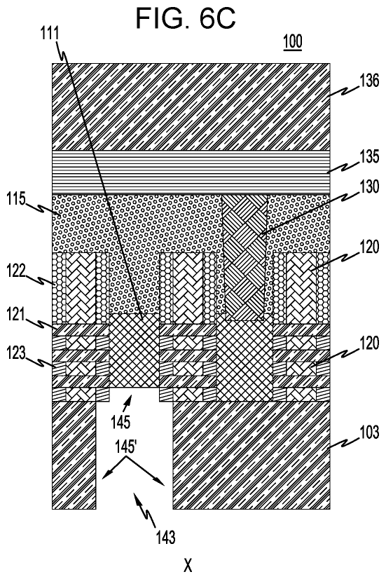

FIGS. 6A, 6B and 6C are schematic cross-sectional views taken along the first y-axis, the second y-axis and the x-axis, and illustrating selective trimming of the exposed semiconductor layer 107 and portions of the second semiconductor substrate 103 from the semiconductor device 100. As shown in FIGS. 6A-6C, portions of the second semiconductor substrate 103 are selectively removed to reduce a vertical thickness of the second semiconductor substrate 103 at a backside end of the semiconductor device 100. In addition, referring to FIGS. 6A and 6C, the semiconductor layer 107 and portions of the second semiconductor substrate 103, including protruding portions 142 (see FIG. 5) of the second semiconductor substrate 103, are selectively removed from the backside contact trench 143 to further increase the area of the backside contact trench 143. Additional vacant areas 145 and 145′ in the backside contact trench 143 are formed by the removal of the semiconductor layer 107 and portions of the second semiconductor substrate 103. An etching processes for removal of the semiconductor layer 107 and portions of the second semiconductor substrate 103 include, for example, IBE by Ar with SF₆ or Cl₂.

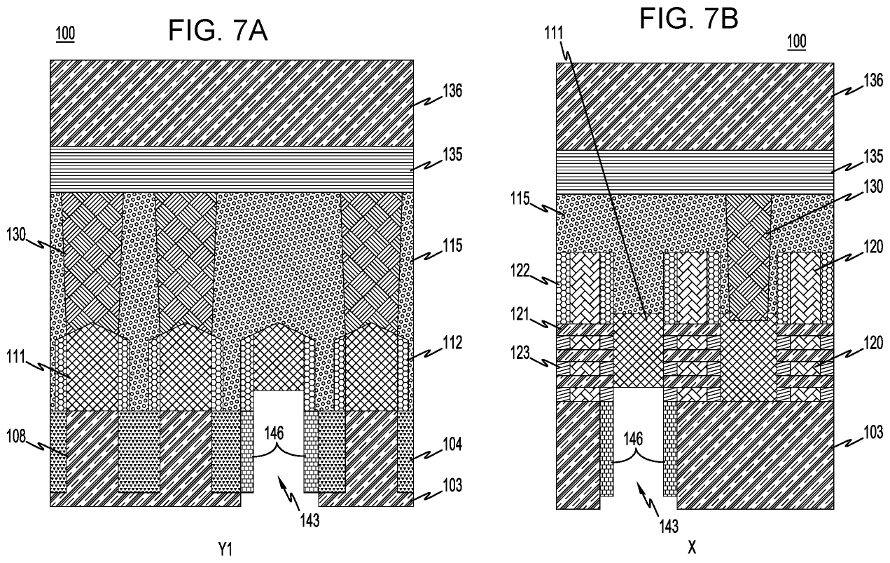

FIGS. 7A and 7B are schematic cross-sectional views taken along the first y-axis and the x-axis, and illustrating sidewall spacer formation in the backside contact trench 143. As shown in FIGS. 7A and 7B, dielectric sidewall spacers 146 are formed in the backside contact trench 143 by deposition techniques such as, for example, CVD, PECVD, RFCVD, PVD, ALD, MBD, PLD, LSMCD, etc., followed by directional etching. Directional etching may include but is not limited to, RIE. The dielectric sidewall spacers 146 are formed from material comprising for example, one or more dielectrics, including, but not necessarily limited to, SiN, SiC, SiON, SiOC, SiCN, BN, SiBN, SiBCN, SiOCN, SiOₓ, and combinations thereof. As can be seen, the dielectric sidewall spacers 146 are formed on exposed side portions of the dielectric layer 104 (isolation region) and the second semiconductor substrate 103 and have a thickness which is the same or about the same as a thickness of the source/drain region spacers 112, the gate spacers 122 and the inner spacers 123.

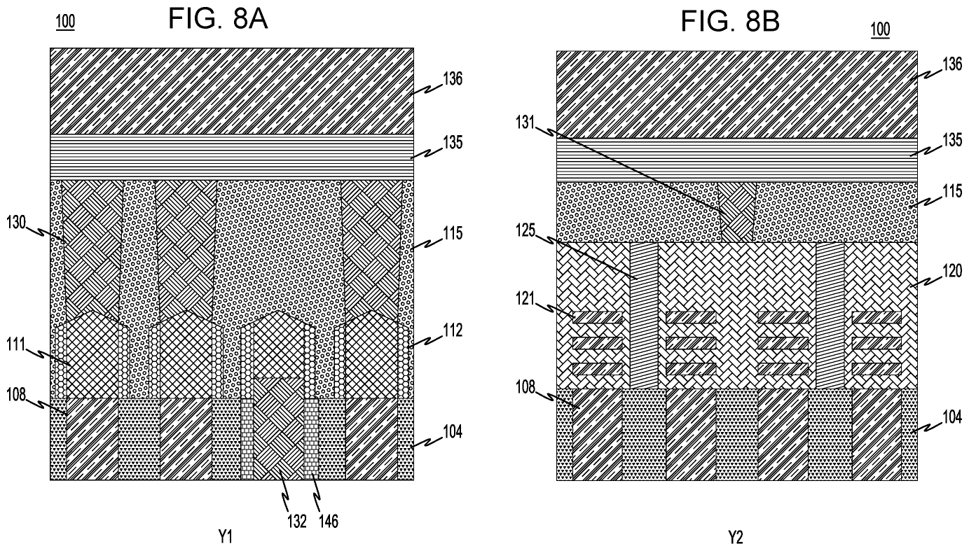

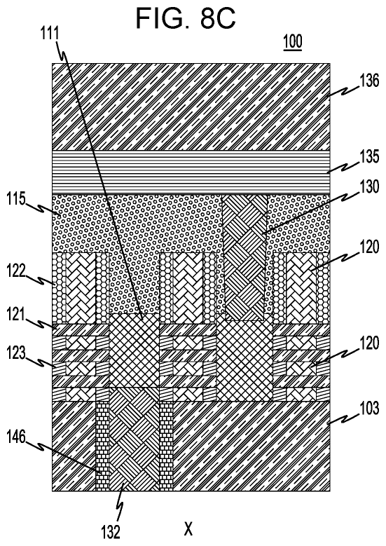

FIGS. 8A, 8B and 8C are schematic cross-sectional views taken along the first y-axis, the second y-axis and the x-axis, and illustrating backside contact metallization and planarization of the semiconductor device 100 following sidewall spacer formation. As can be seen in FIGS. 8A and 8C, a remaining portion of the backside contact trench 143 is filled with a conductive material to form a backside contact via 132 on a source/drain region 111. The conductive material is the same as or similar to the material described for frontside source/drain and gate contact vias 130 and 131, and can be deposited using, for example, a deposition technique such as CVD, PECVD, RFCVD, PVD, ALD, MBD, PLD, LSMCD, sputtering and/or plating, followed by a planarization process such as, ClVIP to remove excess portions of the conductive material from on top of the dielectric layer 104 and remaining portions of the second semiconductor substrate 103, including the pedestal portions 108. Exposed portions of the second semiconductor substrate 103 are removed during the planarization process. Exposed portions of the dielectric layer 104 may also be removed during the planarization process. The number of backside contact vias 132 is not necessarily limited to what is shown in FIGS. 8A and 8C, and may vary depending on design constraints. For example, there may be more than one backside contact via 132 corresponding to other source/drain regions 111.

The backside contact via 132 contacts the source/drain region 111. The backside contact via 132 extends through the second semiconductor substrate 103 and the dielectric layer 104 (isolation regions) to land on and contact the corresponding source/drain region 111. The dielectric sidewall spacers 146 are disposed on sidewalls of the backside contact via 132, and are positioned between the second semiconductor substrate 103 and the backside contact via 132. The dielectric sidewall spacers 146 are also positioned between portions of the dielectric layer 104 (e.g., STI regions) and the backside contact via 132, were the portions of the dielectric layer 104 are adjacent the pedestal portions 108.

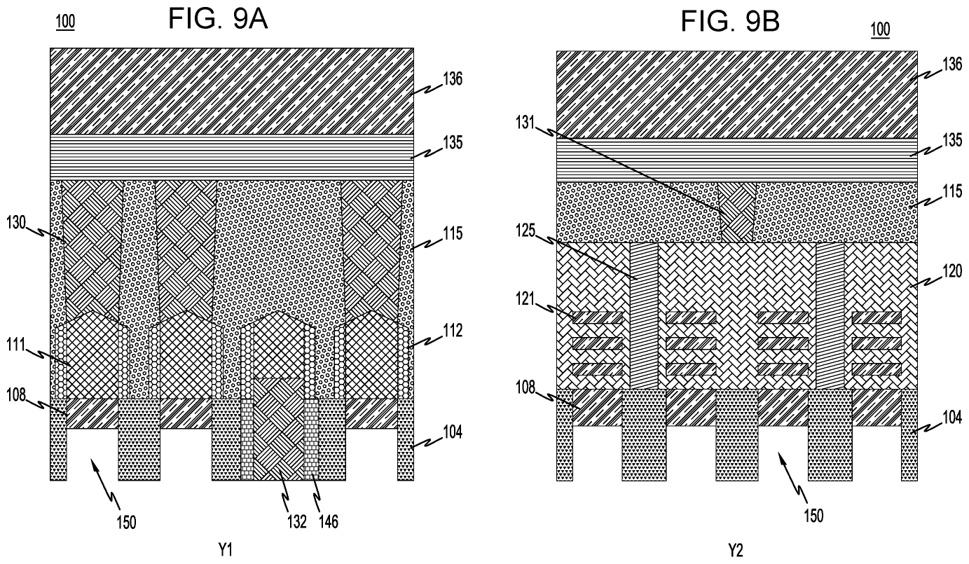

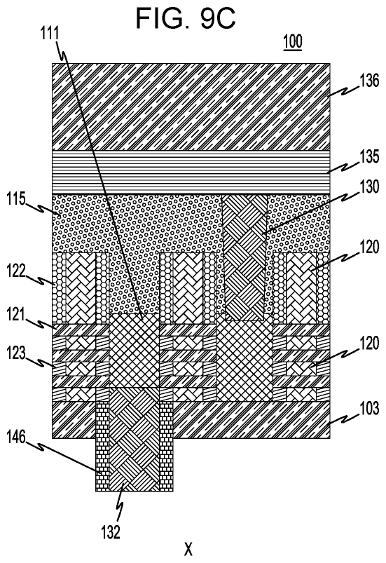

FIGS. 9A, 9B and 9C are schematic cross-sectional views taken along the first y-axis, the second y-axis and the x-axis, and illustrating selective recessing of second semiconductor substrate 103, including pedestal portions 108, following backside contact via metallization. The second semiconductor substrate 103 is selectively recessed by selectively etching the second semiconductor substrate 103, including pedestal portions 108, as illustrated in FIGS. 9A-9C with an etchant that selectively etches silicon with respect to materials of the dielectric layer 104, dielectric sidewall spacers 146 and the backside contact via 132. As can be seen in FIGS. 9A and 9B, the recessing creates vacant areas 150 between portions of the dielectric layer 104 (e.g., STI regions).

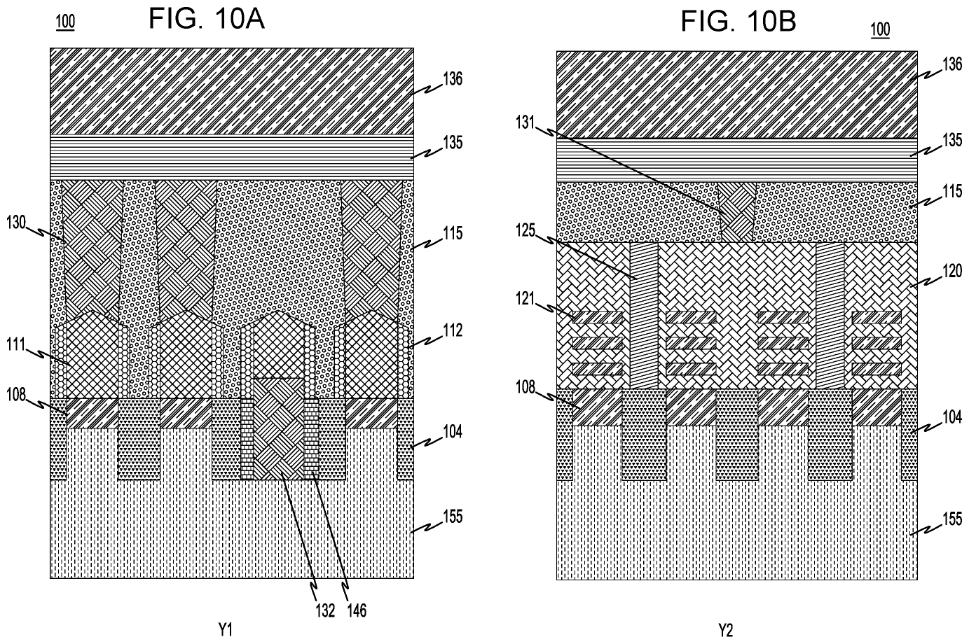

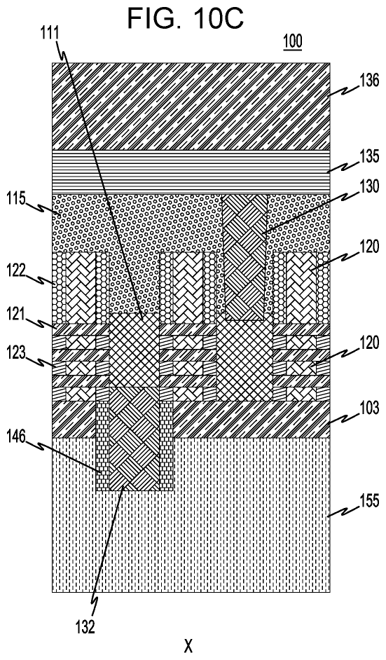

FIGS. 10A, 10B and 10C are schematic cross-sectional views taken along the first y-axis, the second y-axis and the x-axis, and illustrating deposition of a backside ILD layer 155 following recessing of the second semiconductor substrate 103. The backside ILD layer 155 comprises the same or similar material to that of the ILD layer 115, and is deposited using one or more of the same or similar deposition techniques used for depositing the ILD layer 115. As can be seen in FIGS. 10A-10C, the backside ILD layer 155 is deposited on the second semiconductor substrate 103, including pedestal portions 108, on the portions of the dielectric layer 104, on the dielectric sidewall spacers 146 and on the backside contact via 132. The backside ILD layer 155 fills in the vacant areas 150.

FIGS. 11A, 11B and 11C are schematic cross-sectional views taken along the first y-axis, the second y-axis and the x-axis, and illustrating power element and power delivery network layer formation following deposition of a backside ILD layer 155. Backside power rails 161 and 162, also referred to herein as power elements, are formed in the backside ILD layer 155 by forming trenches in the backside ILD layer 155 and filling the trenches with conductive material. Trenches are respectively opened in the backside ILD layer 155 using, for example, lithography followed by ME. The backside power rails 161 and 162 are formed in the trenches by filling the trenches with conductive material, such as, for example, electrically conductive material including, but not necessarily limited to, tungsten, cobalt, zirconium, tantalum, titanium, aluminum, ruthenium, and/or copper. A liner layer (not shown) including, for example, titanium and/or titanium nitride, may be formed on side and bottom surfaces of the trenches before filling the trenches with the conductive material. Deposition of the conductive material can be performed using one or more deposition techniques, including, but not necessarily limited to, CVD, PECVD, PVD, ALD, MBD, PLD, LSMCD, and/or spin-on coating, followed by planarization using a planarization process, such as, for example, CMP.

Although a connection to a source/drain region 111 by the backside power rail 161 is not shown, the backside power rail 161 delivers, for example, source voltage (VSS) to a corresponding source/drain region 111 to which the backside power rail 161 is connected. The backside power rail 162 delivers, for example, drain voltage (VDD) through the backside contact via 132 to the corresponding source/drain region 111 which the backside contact via 132 contacts. As can be seen in FIGS. 11A and 11C, the backside contact via 132 contacts the source/drain region 111, and the backside power rail 162 is formed on and contacts the backside contact via 132. The backside contact via 132 extends through the remaining portions of the second semiconductor substrate 103 and the dielectric layer 104 (isolation regions) to land on and contact the corresponding source/drain region 111. The backside ILD layer 155 fills in the vacant areas 150 under the remaining portions of the second semiconductor substrate 103 on lateral sides of the backside contact via 132. The dielectric sidewall spacers 146 are disposed on sidewalls of the backside contact via 132, and are positioned between the second semiconductor substrate 103 and the backside contact via 132. The dielectric sidewall spacers 146 are also positioned between portions of the dielectric layer 104 (e.g., STI regions) and the backside contact via 132, where the portions of the dielectric layer 104 are adjacent the remaining portions of the second semiconductor substrate (e.g., remaining pedestal portions 108) and the parts of the backside ILD layer 155 filling in the vacant areas 150. A portion of a dielectric sidewall spacer 146 contacts a part of the backside ILD layer 155 located between backside power rails 161 and 162. As can be seen in FIG. 11A, the portion of the dielectric sidewall spacer 146 is on top of the part of the backside ILD layer 155. The dielectric sidewall spacers 146 also contact the backside power rail 162. As can be seen in FIGS. 11A and 11C, the dielectric sidewall spacers 146 are formed along sidewalls of the backside contact via 132 and on top of the backside power rail 162. As shown in FIG. 11C, portions of the dielectric sidewall spacers 146 are positioned between the backside ILD layer 155 and the backside contact via 132, and other portions of the dielectric sidewall spacers 146 are positioned between remaining portions of the second semiconductor substrate 103 and the backside contact via 132. The dielectric sidewall spacers 146 extend vertically from the backside power rail 162 along a sidewalls of the backside contact via 132.

Backside power delivery network (BSPDN) layers 157 are formed on the backside ILD layer 155. The backside power delivery network layers 157 include various BSPDN structures such as, but not necessarily limited to, interconnects in a power supply path from voltage regulator modules (VRMs) to circuits. The interconnects can comprise, for example, power and ground planes in circuit boards, cables, connectors and capacitors associated with a power supply. Backside power delivery prevents BEOL routing congestion, resulting in power performance benefits.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

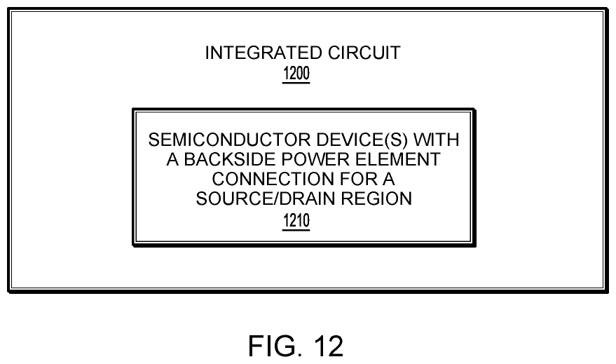

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 12 shows an example integrated circuit 1200 which includes one or more semiconductor devices 1210 with the above-described backside power element connection (e.g., backside contact via 132) for a source/drain region.

As noted above, illustrative embodiments correspond to methods for forming a backside power element connection to a source/drain region, where a dielectric sidewall spacer separates a backside contact via from a semiconductor layer, along with illustrative apparatus, systems and devices formed using such methods. The backside contact via is separated from remaining portions of a semiconductor substrate by a dielectric spacer, which also directly touches STI regions and a backside ILD layer. The backside contact via passes through the remaining portions of a semiconductor substrate and a backside ILD layer, and connects to a backside power rail, while using the same spacing or decreased spacing between transistors when compared with conventional structures. The dielectric spacer prevents shorts or other device failures between transistors while maintaining the same or smaller footprints.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device, comprising:
a transistor disposed on a semiconductor substrate, wherein the transistor comprises a source/drain region disposed on a first side of the semiconductor substrate;
a via extending through the semiconductor substrate, wherein the via connects a power element disposed on a second side of the semiconductor substrate to the source/drain region; and
a dielectric spacer disposed between the via and the semiconductor substrate.

2. The semiconductor device of claim 1, wherein the power element comprises a power rail.

3. The semiconductor device of claim 1, wherein the dielectric spacer is disposed on a sidewall of the via.

4. The semiconductor device of claim 1, further comprising an isolation region disposed between the dielectric spacer and the semiconductor substrate.

5. The semiconductor device of claim 4, wherein the isolation region comprises a shallow trench isolation region.

6. The semiconductor device of claim 1, further comprising an inter-layer dielectric layer disposed on the second side of the semiconductor substrate adjacent the power element, wherein at least a portion of the dielectric spacer contacts the inter-layer dielectric layer.

7. The semiconductor device of claim 1, wherein at least a portion of the dielectric spacer contacts the power element.

8. The semiconductor device of claim 1, wherein the transistor comprises a plurality of gate structures alternately stacked with a plurality of channel layers, and the source/drain region is connected to the plurality of channel layers.

9. The semiconductor device of claim 8, wherein the source/drain region is positioned on a lateral side of the plurality of gate structures and the plurality of channel layers.

10. The semiconductor device of claim 1, wherein the dielectric spacer extends from the power element along a sidewall of the via.

11. The semiconductor device of claim 1, further comprising:
one or more additional transistors on the semiconductor substrate, wherein the one or more additional transistors comprise one or more additional source/drain regions; and
one or more additional vias disposed on the one or more additional source/drain regions, wherein the one or more additional vias are disposed on the first side of the semiconductor substrate.

12. An integrated circuit comprising:
a transistor disposed on a semiconductor layer, wherein the transistor comprises a source/drain region disposed on a first side of the semiconductor layer;
an isolation region disposed in the semiconductor layer; and
a via extending through the semiconductor layer, wherein the isolation region is disposed between the via and the semiconductor layer, and wherein the via connects a power element disposed on a second side of the semiconductor layer to the source/drain region.

13. The integrated circuit of claim 12, wherein the power element comprises a power rail.

14. The integrated circuit of claim 12, further comprising:
a dielectric spacer disposed between the via and the isolation region; and
an inter-layer dielectric layer disposed on the second side of the semiconductor layer adjacent the power element, wherein at least a portion of the dielectric spacer contacts the inter-layer dielectric layer.

15. The integrated circuit of claim 14, wherein the dielectric spacer extends from the power element along a sidewall of the via.

16. A semiconductor device, comprising:
a source/drain region disposed on a first side of a semiconductor layer;
a power element disposed on a second side of the semiconductor layer; and
a via extending through the semiconductor layer and between the power element and the source/drain region.

17. The semiconductor device of claim 16, wherein the power element comprises a power rail.

18. The semiconductor device of claim 16, further comprising a dielectric spacer disposed between the via and the semiconductor layer and on a sidewall of the via.

19. The semiconductor device of claim 18, further comprising an isolation region disposed between the dielectric spacer and the semiconductor layer.

20. The semiconductor device of claim 19, wherein the dielectric spacer extends along a side of the isolation region.
